(19) United States
(12) Patent Application Publication
(10) Pub. No.: US 2011/0188221 A1
(43) Pub. Date: Aug. 4, 2011

(54) Extended player

(75) Inventor: Chia-I Liu, Jhonghe City (TW)

(73) Assignee: E-Flycom Corp.

(21) Appl. No.: 12/071,166

(22) Filed: Feb. 15, 2008

(51) Int. Cl. H05K 7/02; H04R 1/02; G09G 5/00

(52) U.S. Cl. 361/807; 381/386; 345/1.1

(57) ABSTRACT

An extended player, which, after establishing a signal connection with a multimedia player, is able to play back multimedia files through built-in speakers or a display unit to achieve better image and sound effectiveness. The present invention uses a rotary table or a slide rail to enable rotation of a multimedia player to an applicable operating angle, thereby substantially increasing convenience when operating a multimedia player.

### BACKGROUND OF THE INVENTION

(a) Field of the Invention

The present invention provides an extended player able to rotate a multimedia player to an applicable operating angle while maintaining a signal connection state therewith.

(b) Description of the Prior Art

Following technical progress in the video electronic industry, an increasing number of corresponding player devices have emerged, in particular, the innumerable common portable multimedia players, such as the ipod, ipod nano, ipod touch, ipod video, mp3 or mp4, and the like, and such portable multimedia players not only provide the effectiveness to play back sound files (such as MP3, WMV or WMA sound files), but are also able to play back image and sound files (including static image files and dynamic video files). Apart from having a reduced size which increases convenience of use thereof, some multimedia players are provided with additional functionality, for example: sound recording, video filming and gaming.

However, because of size limitations, effectiveness of video playback is limited for the majority of portable multimedia players, and is not convenient when used at home. Hence, an extended player must be used to increase the sound effectiveness when playing sound files. Referring to FIG. 1, which shows an implementation schematic view of an extended player of the prior, wherein an extended player 10 is formed with a slot 101 that enables a multimedia player 20 to be inserted therein. A signal interface 102 is disposed on an inner side of the slot 101, thereby enabling a signal connection to be established with the multimedia player 20 to enable transmission of various types of multimedia files. However, presently, some of the multimedia players 20 are provided with screen rotating functionality (whereby the screen can be changed from portrait mode to landscape mode), and touch screen control design. Accordingly, the operating angle of the multimedia player 20 changes after rotating the screen thereof, and is thus unsuitable for use with fixed angle type extended players of the prior art.

### SUMMARY OF THE INVENTION

In light of the unsuitability of some multimedia players being used on fixed angle type extended players of the prior art, and thus affecting image and sound effectiveness when playing, the inventor of the present invention has meticulously carried out extensive study and exploration to ultimately design a new improved extended player.

A primary objective of the present invention is to provide an extended player with rotating placement angle functionality.

In order to achieve the aforementioned objective, the extended player of the present invention comprises at least an outer casing, a rotary table and built-in player modules, wherein the built-in player modules can be common speakers or a display unit, accordingly, after a multimedia player is made to establish a signal connection with the present invention, then the built-in speakers or the display unit is used to play back multimedia files. Because the power of the built-in speakers of the present invention is relatively greater compared to the original multimedia player, and size of the screen of the display unit is substantially larger than the screen of the original multimedia player, thus, the present invention is able to achieve better image and sound effectiveness. The present invention primarily includes a holding recess formed in the outer casing, and an electric connecting portion is disposed on an annular edge of the holding recess of the outer casing, moreover, a corresponding electric connecting portion is disposed on an outer periphery of the rotary table. The rotary table is movable pivot disposed within the holding recess of the outer casing, thereby enabling rotation of the rotary table through any arbitrary angle relative to the outer casing (that is, the outer casing remains stationary while the rotary table rotates). Furthermore, a signal interface is disposed on the rotary table, and the signal interface enables a signal connection to be established with a multimedia player through the signal interface connecting with the corresponding electric connecting portion. Hence, after a signal connection is established between the corresponding electric connecting portion and the electric connecting portion of the outer casing, then the multimedia player is able to establish a signal connection with the built-in player module of the present invention, moreover, rotating the rotary table causes a corresponding rotation of the multimedia player, thereby changing operating angle of the multimedia player, and substantially increasing convenience when operating the multimedia player.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 shows an implementation schematic view of an extended player of the prior art.

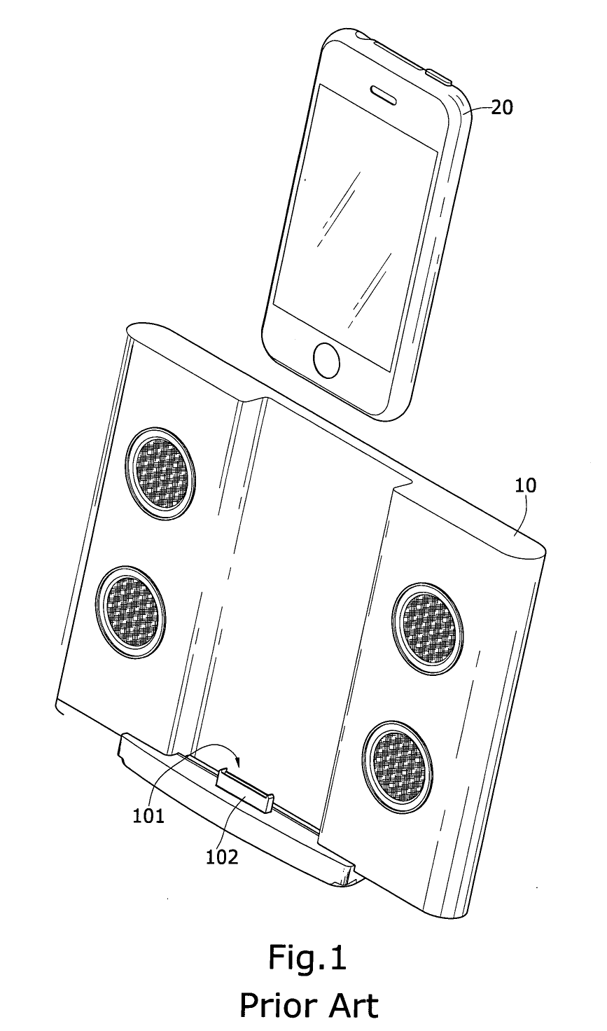

FIG. 2 shows an implementation schematic view of a preferred embodiment according to the present invention.

FIG. 3 shows an exploded elevational view of a preferred embodiment according to the present invention.

FIG. 4 shows another view of a rotary table of the preferred embodiment according to the present invention.

FIG. 5 shows a structural schematic view of another preferred embodiment according to the present invention.

FIG. 6 shows a structural schematic view of yet another preferred embodiment according to the present invention.

### DETAILED DESCRIPTION OF THE PREFERRED EMBODIMENTS

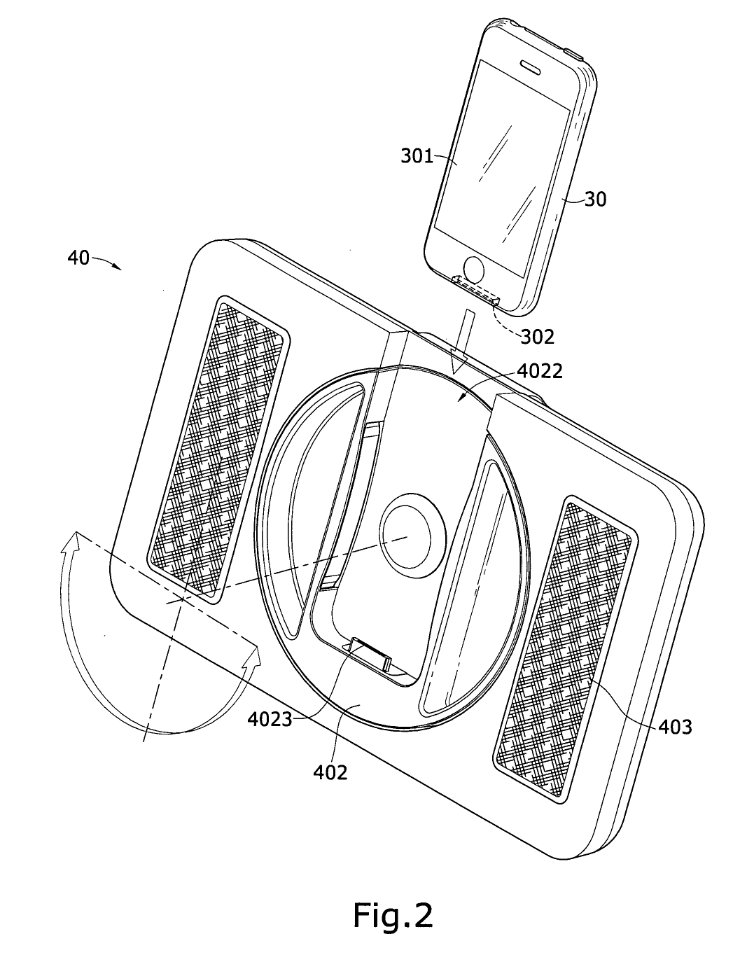

Referring to FIG. 2, which shows a schematic view of a preferred embodiment according to the present invention, wherein, taking an ipod touch multimedia player as an example, a multimedia player 30 is fitted with a touch control screen 301 and a signal interface 302, and an earphone can be used to establish a signal connection with the signal interface 302 and enable the playing of sound files. The touch control screen 301 is used to enable the playing of video files or can function to operate various options when playing. After the multimedia player 30 is inserted into a slot 4022 of a rotary table 402 of the present invention, then a signal interface 4023 disposed at a front face is used to establish a signal connection with the signal interface 302 of the multimedia player 30, thereby enabling play back functionality of the multimedia player 30 to be transferred through the referral interfaces of the signal interfaces 302 and 4023 to built-in player modules 403 of an extended player 40 of the present invention to enable the playing of multimedia files and achieve better image and sound effectiveness. The present invention is primary characterized in that it enables rotation of the multimedia player 30 to adjust operating angle of the multimedia player 30 for use thereof, thereby facilitating use of the multimedia player 30 provided with screen rotation functionality.

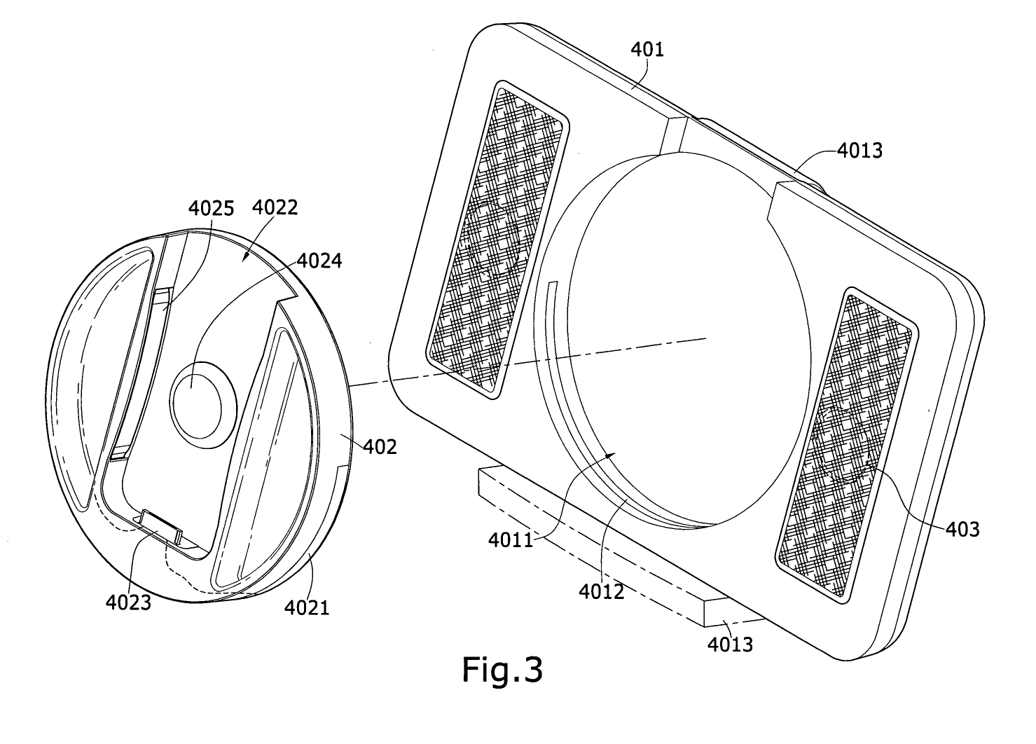

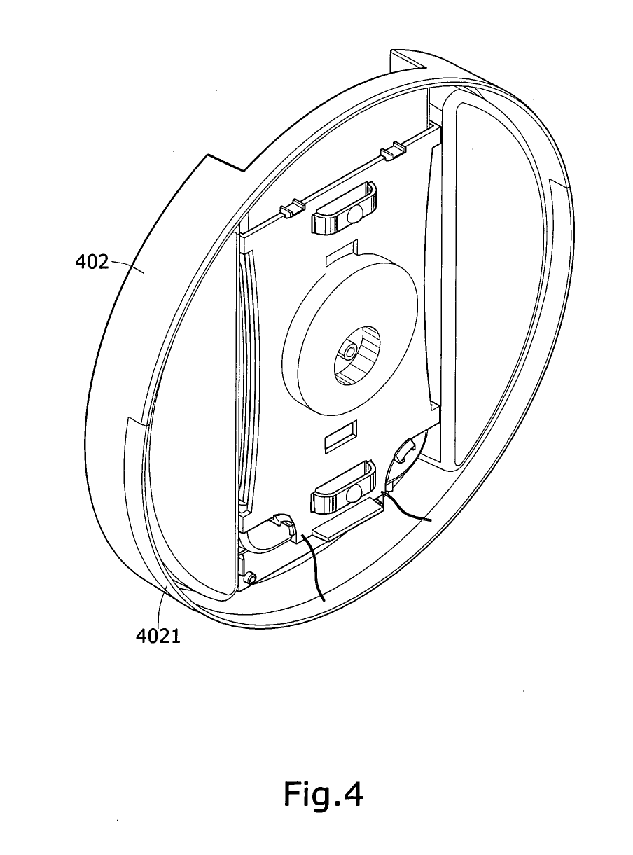

Referring to FIG. 3, which shows an exploded elevational view of a preferred embodiment according to the present invention, wherein the aforementioned extended player 40 comprises at least an outer casing 401, a holding recess 4011 is formed in a front face of the outer casing 401, and an electric connecting portion 4012 is disposed on an annular edge of the holding recess 4011, moreover, one side of the outer casing 401 has a base 4013 formed as an integral body, or the base 4013 is movable pivotal disposed to the outer casing 401. When normally not in use, the movable pivotal disposed base 4013 can be rotated into a correspondingly formed groove of the outer casing 401 for placement therein, and the outer casing 401 can be made to stand upright by rotating the base 4013 out from the groove. The rotary table 402 movable pivotal disposed within the holding recess 4011 enables the rotary table 402 to be rotated 90 degrees clockwise or anti-clockwise relative to the outer casing 401, thereby providing a total 180 degree angular adjustment range. A corresponding electric connecting portion 4021 is disposed on an outer periphery of the rotary table 402 (see FIG. 4, which depicts another view of the rotary table 402 of the preferred embodiment according to the present invention, wherein the corresponding electric connecting portion 4021 is designed to cover the outer peripheral edge of the rotary table 402 all the way to the rear thereof). Moreover, the slot 4022 formed in the front face of the rotary table 402 enables the aforementioned multimedia player 30 to be inserted and disposed therein, and the signal interface 4023 disposed on one side of the slot 4022 enables a signal connection to be realized between the corresponding electric connecting portion 4021 and the signal interface 4023. In addition, an abutting portion 4024 is located at the center portion of the slot 4022, and is used to facilitate taking out the aforementioned multimedia player 30 after being inserted therein. Moreover, two sides of the slot 4022 are respectively assembled with a spring piece 4025, and the spring pieces 4025 enable clamping the aforementioned multimedia player 30. Moreover, the set of built-in player modules 403 are assembled within the outer casing 401, and a signal connection is established between the built-in player modules 403 and the electric connecting portion 4012 of the outer casing 401. Furthermore, the built-in player modules 403 are speakers. When using the present invention, the aforementioned multimedia player 30 is inserted into the slot 4022 of the rotary table 402, thereby causing the aforementioned signal interface 302 of the multimedia player 30 to establish a signal connection with the signal interface 4023 of the rotary table 402, and after a signal connection is established between the corresponding electric connecting portion 4021 of the rotary table 402 and the electric connecting portion 4012 of the outer casing 401, then transmission of multimedia files of the multimedia player 30 is enabled and the built-in player modules 403 are able to play back the multimedia files. However, operation must still be carried out using the aforementioned touch control screen 301 of the multimedia player 30. Hence, when the screen of the aforementioned multimedia player 30 is rotated, then the present invention enables fast rotation of the rotary table 402 to a corresponding angle, thereby facilitating the user in accommodating operation of the changed operating angle of the aforementioned multimedia player 30.

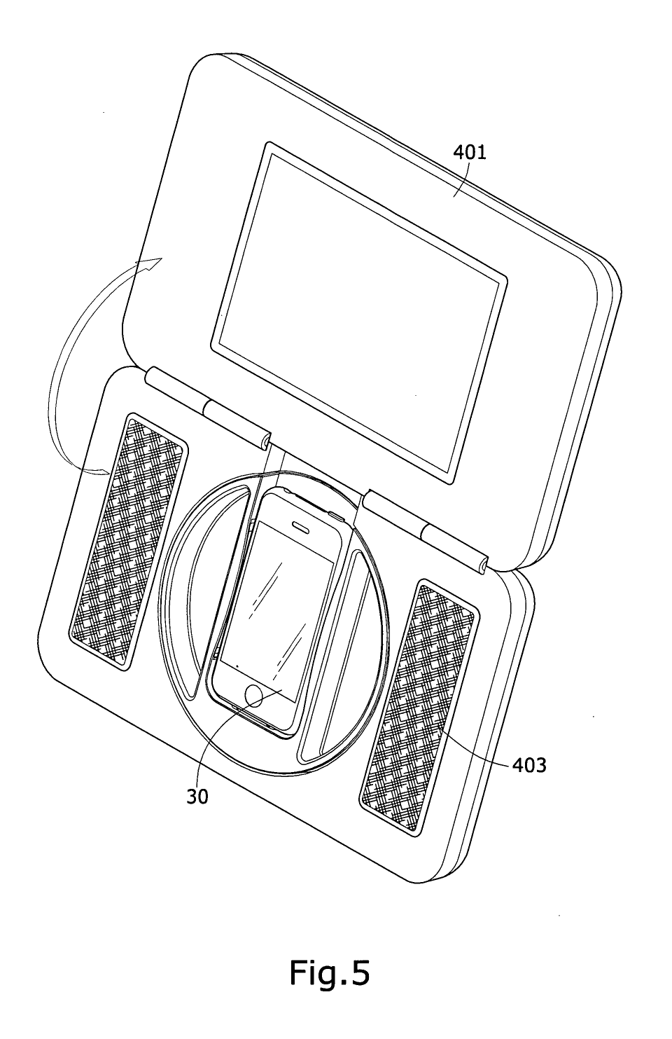

Referring to FIG. 5, which shows a structural schematic view of another preferred embodiment according to the present invention structure, wherein the aforementioned built-in player modules 403 are speakers combined with a display unit, and the display unit is movable pivotal disposed on one side of the outer casing 401, thereby enabling multimedia files (sound files and video files) to be played back after a signal connection is established with the aforementioned multimedia player 30. When normally not in use, the display unit can be folded to the front of the outer casing 401.

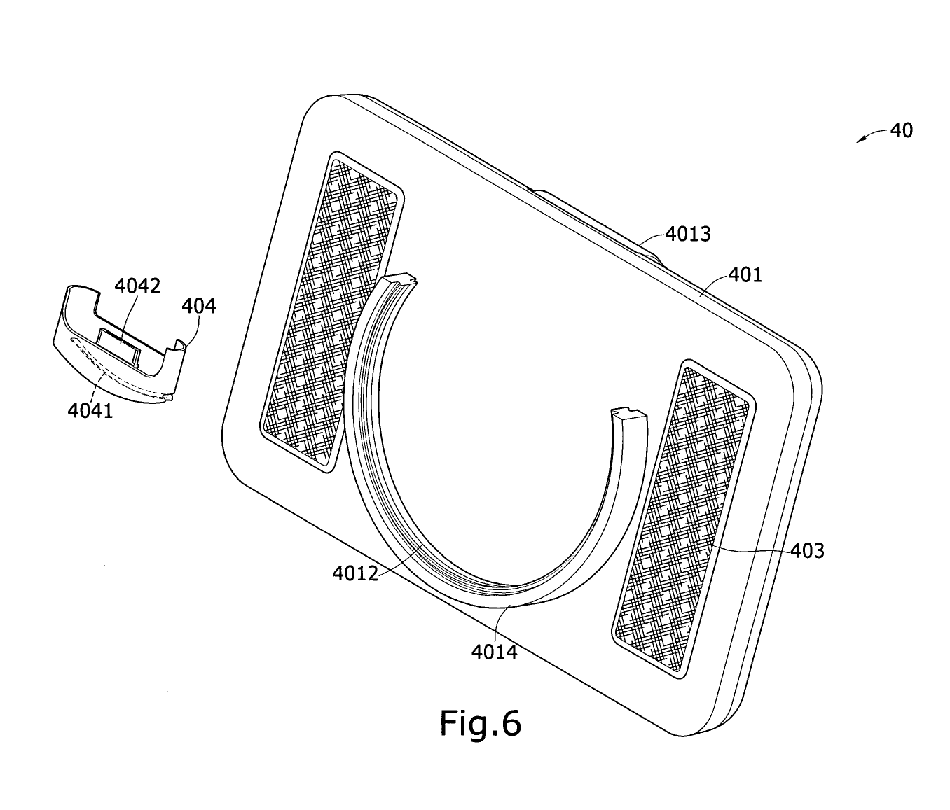

Referring to FIG. 6, which shows a structural schematic view of yet another preferred embodiment according to the present invention, wherein the embodiment of the aforementioned extended player 40 depicted also enables rotation of the aforementioned multimedia player 30, and comprises at least the outer casing 401, and an arc-shaped slide rail 4014 is formed on a front surface of the outer casing 401 (and protrudes out from the front surface of the outer casing 401). The electric connecting portion 4012 is disposed on an annular edge of the arc-shaped slide rail 4014, and one side of the outer casing 401 is provided with the base 4013 formed as an integral body. A slide piece 404 is slide disposed on the arc-shaped slide rail 4014, and the slide piece 404 is able to rotate 90 degrees clockwise or anti-clockwise relative to the outer casing 401, thereby providing a total 180 degree angular adjustment range. Moreover, a corresponding electric connecting portion 4041 is disposed on the slide piece 404 corresponding to the arc-shaped slide rail 4014. Furthermore, a signal interface 4042 is disposed on the slide piece 404, thereby enabling the corresponding electric connecting portion 4041 to establish a signal connection with the signal interface 4042. Moreover, the built-in player modules 403 are assembled within the outer casing 401 to enable the built-in player modules 403 to establish a signal connection with the electric connecting portion 4012 of the outer casing 401. In addition, the built-in player modules 403 are speakers, hence, when the aforementioned multimedia player 30 is inserted into the slide piece 404, then a signal connection is established between the multimedia player 30 and the present invention, thereby enabling the playing of sound files within the multimedia player 30.

According to what has been described above, the extended player 40 of the present invention uses the rotary table 402 disposed within the corresponding holding recess 4011 of the outer casing 401 or the slide piece 404 disposed on the corresponding arc-shaped slide rail 4014 to achieve rotation of placement angle of a multimedia player, thereby increasing operability of the multimedia player.

In conclusion, the extended player 40 of the present invention is provided with patent novelty and high industrial utility value, accordingly, the inventor of the present invention hereby proposes an application for a new patent as disclosed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. An extended player, comprising at least:
an outer casing, one side of the outer casing is formed with a holding recess, and an electric connecting portion is disposed on an annular edge of the holding recess;
a rotary table movable pivotal disposed within the holding recess, a corresponding electric connecting portion is disposed on an outer periphery of the rotary table, and a signal interface is disposed on the rotary table, the corresponding electric connecting portion enables a signal connection to be established with the signal interface, and a set of built-in player modules assembled within the outer covering, the built-in player modules establish a signal connection with the electric connecting portion of the outer casing.

2. The extended player according to claim 1, wherein one side of the outer casing has a base formed as an integral body.

3. The extended player according to claim 1, wherein one side of the outer casing has a base movable pivotal disposed thereto.

4. The extended player according to claim 1, wherein the rotary table rotates 90 degrees clockwise or anti-clockwise relative to the outer casing.

5. The extended player according to claim 1, wherein the rotary table is formed with a slot, and a signal interface is disposed on one side of the slot.

6. The extended player according to claim 1, wherein an abutting portion is located on one surface of the slot, and two sides of the slot are respectively assembled with a spring piece.

7. The extended player according to claim 1, wherein the built-in player modules are speakers.

8. The extended player according to claim 1, wherein the built-in player modules is a display unit.

9. The extended player according to claim 8, wherein the display unit is movable pivotal disposed to one side of the outer casing.

10. The extended player according to claim 1, wherein the built-in player modules is a set of speakers combined with a display unit.

11. The extended player according to claim 10, wherein the display unit is movable pivotal disposed to one side of the outer casing.
